(19) United States
(12) Patent Application Publication
(10) Pub. No.: US 2004/0217702 A1
(43) Pub. Date: Nov. 4, 2004

(54) Light extraction designs for organic light emitting diodes

(76) Inventors: Sean M. Garner, Elmira, NY (US); Venkata A. Bhagavatula, Big Flats, NY (US); James S. Sutherland, Corning, NY (US); MacRae Maxfield, Teaneck, NY (US); Karl Beeson, Printon, NJ (US); Lawrence W. Shacklette, Maplewood, NJ (US); Peng Jiang, Plainsboro, NJ (US); Han Zou, Windsor, NJ (US)

Correspondence Address: CORNING INCORPORATED, SP-TI-3-1, CORNING, NY, 14831

(21) Appl. No.: 10/638,030

(22) Filed: Aug. 8, 2003

Related U.S. Application Data
(60) Provisional application No. 60/467,725, filed on May 2, 2003.

(51) Int. Cl. H05B 33/04; H01J 9/00

(52) U.S. Cl. 313/512; 445/24

(57) ABSTRACT

A light emitting device (e.g., organic light emitting diode (OLED)) and a method for manufacturing the OLED are described herein. Basically, the OLED includes a substrate, a first conductive electrode, at least one organic layer, a second conductive electrode, an encapsulant substrate and a microstructure. The microstructure has internal refractive index variations or internal or surface physical variations that function to perturb the propagation of internal waveguide modes within the OLED and as a result allows more light to be emitted from the OLED. Several different embodiments of the microstructure that can be incorporated within an OLED are described herein.

### CLAIMING BENEFIT OF PRIOR FILED PROVISIONAL APPLICATION

This application claims the benefit of U.S. Provisional Application Ser. No. 60/467,725 (Attorney Docket No. SP03-055P) filed on May 2, 2003 and entitled “Light Extraction Designs for Organic Light Emitting Diodes” which is incorporated by reference herein.

### BACKGROUND OF THE INVENTION

1. Field of the Invention

The present invention relates to light emitting devices, and more particularly to organic light emitting diodes (OLEDs) and methods for improving the emission efficiency of the OLEDs.

2. Description of Related Art

OLEDs including small-molecule organic LEDs (SMOLEDs) and polymer LEDs (PLEDs) are solid structures that convert electrical power to light and emit a portion of the light through a transparent substrate. As shown in FIG. 1, the traditional OLED 100 includes a multi-layer sandwich of a planar transparent substrate 102, an anode electrode 104, one or more organic layers 106, a cathode electrode 108 and an encapsulant substrate 110. For simplicity, the discussion herein is based on a single organic layer 106 where the light emission occurs. However, those skilled in the art will readily appreciate that the discussion that follows can be readily extended to more complicated organic structures.

The traditional OLED 100 has a relatively poor efficiency of conversion of input voltage 112 to emitted light (e.g. rays 114a) that escapes the OLED 100. In particular and as shown in FIG. 1, the light 114a, 114b and 114c generated in the organic layer 106 radiates in all directions and impacts the interface between the anode conductor 104 and substrate 102 at low angles which are near orthogonal (or near normal incidence) to the interface and at high angles. In this case, low angle and high angle refers to the angle the ray makes with respect to a line orthogonal to the planar substrate surface. The low angle light 114a is refracted but is eventually extracted from the organic layer 106 and emitted out from the OLED 100. But, since the organic layers 106 and anode electrode 104 have a higher index of refraction than the substrate 102, most of the high angle light 114b meets the condition for total internal reflection within the OLED 100. In addition, most of the light 114c that is incident on the substrate-air interface does not escape due to total internal reflection. Thus, an estimated 70% to 80% of light 114a, 114b, and 114c produced in the organic layers 106 is not available for use because the high angle light 114b and 114c is trapped inside the OLED 100.

The trapped light 114b and 114c and its associated optical power is lost due to multiple internal reflections or waveguiding within the organic layer 106, anode electrode 104 and substrate 102. The waveguided power is either absorbed by the organic layer 106 and electrodes 104, 108 or propagated to the edge of the OLED 100. In either case, the low out-coupling efficiency in the OLED 100 translates to wasted power and drastically reduces the overall efficiency of the OLED 100. This low out-coupling efficiency of the OLED 100 is a problem since many manufactures of OLED displays and OLED lighting devices are demanding OLEDs 100 with an out-coupling efficiency of more than 45%. To date several references have described different techniques for improving the out-coupling efficiency of an OLED by using external lenses, high index substrates, aerogel layers, external features on the substrate etc. These techniques are described in detail in the following references, each of which is incorporated herein by reference:

U.S. Pat. Nos. 6,323,063; 6,091,406; 6,420,031; 5,739,545; and 6,046,543.

U.S. Patent Application No. 2002/0117663.

PCT Patent Application Nos. WO 01/33598 and WO 01/24290.

C. F. Madigan et al. “Improvement of output coupling efficiency of organic light-emitting diodes by backside substrate modification”, Applied Physics Letters, Vol. 76, No. 13, pages 1650-1652, Mar. 27, 2000.

S. Möller et al. “Improved light out-coupling in organic light emitting diodes employing ordered microlens arrays”, Journal of Applied Physics, Vol. 91, No. 5, pages 3324-3327, Mar. 1, 2002.

J. R. Lawrence et al. “Optical properties of a light-emitting polymer directly patterned by soft lithography”, Applied Physics Letters, Vol. 81, No. 11, pages 1955-1957, Sep. 9, 2002.

B. J. Matterson et al. “Increased Efficiency and Controlled Light Output from a Microstructured Light-Emitting Diode”, Advanced Materials, Vol. 13, No. 2, pages 123-127, Jan. 16, 2001.

T. Yamasaki et al. “Organic light-emitting device with an ordered monolayer of silica microspheres as a scattering medium”, Applied Physics Letters, Vol. 76, No. 10, pages1243-1245, Mar. 6, 2000.

U.S. Patent Application No. 2002/0033135.

Although all of these known techniques increase the out-coupling efficiency or light extraction of the OLED 100, most are not practical for high volume manufacturing of active matrix OLED displays. Also, most if not all of these known techniques fail to simultaneously reduce the problematical waveguiding in the organic layer 106, anode electrode 104 and substrate 102 of the OLED 100. Accordingly, there is a need to address the aforementioned shortcomings and other shortcomings of the traditional OLED 100. These needs and other needs are satisfied by the OLED and the method for manufacturing the OLED of the present invention.

### BRIEF DESCRIPTION OF THE INVENTION

The present invention includes a light emitting device (e.g., organic light emitting diode (OLED)) and a method for manufacturing the light emitting device. Basically, the OLED includes a substrate, a first conductive electrode, at least one organic layer, a second conductive electrode, an encapsulant substrate and a microstructure. The microstructure has internal refractive index variations or internal or surface physical variations that function to perturb the propagation of internal waveguide modes within the OLED and as a result allows more light to be emitted from the OLED. Several different embodiments of the microstructure that can be incorporated within an OLED are described herein.

### BRIEF DESCRIPTION OF THE DRAWINGS

A more complete understanding of the present invention may be had by reference to the following detailed description when taken in conjunction with the accompanying drawings wherein:

FIG. 1 (PRIOR ART) is a cross-sectional side view illustrating the basic components of a traditional OLED;

FIG. 2 is a cross-sectional side view illustrating the basic components of an OLED in accordance with the present invention;

FIG. 3 is a cross-sectional side view illustrating in greater detail an OLED device containing an array of OLEDs each configured in accordance with a first embodiment of the OLED shown in FIG. 2;

FIG. 4 is a flowchart illustrating the steps of a preferred method for manufacturing the OLED device incorporating the first embodiment of the OLEDs shown in FIG. 3;

FIGS. 5A-5I are cross-sectional side views of the first embodiment of the OLEDs at different steps in the method shown in FIG. 4;

FIG. 6 is a cross-sectional side view illustrating in greater detail an OLED device containing an array of OLEDs each configured in accordance with a second embodiment of the OLED shown in FIG. 2;

FIG. 7 is a flowchart illustrating the steps of a preferred method for manufacturing the OLED device incorporating the second embodiment of the OLEDs shown in FIG. 6;

FIGS. 8A-8I are cross-sectional side views of the second embodiment of the OLEDs at different steps in the method shown in FIG. 7;

FIG. 9 is a cross-sectional side view illustrating in greater detail an OLED device containing an array of OLEDs each configured in accordance with a third embodiment of the OLED shown in FIG. 2;

FIG. 10 is a cross-sectional side view illustrating in greater detail an OLED device containing an array of OLEDs each configured in accordance with a fourth embodiment of the OLED shown in FIG. 2;

FIG. 11 is a cross-sectional side view illustrating in greater detail an OLED device containing an array of OLEDs each configured in accordance with a fifth embodiment of the OLED shown in FIG. 2;

FIG. 12 is a cross-sectional side view illustrating in greater detail an OLED device containing an array of OLEDs each configured in accordance with a sixth embodiment of the OLED shown in FIG. 2;

FIG. 13 is a cross-sectional side view illustrating in greater detail an OLED device containing an array of OLEDs each configured in accordance with a seventh embodiment of the OLED shown in FIG. 2;

FIG. 14 is a cross-sectional side view illustrating in greater detail an OLED device containing an array of OLEDs each configured in accordance with an eighth embodiment of the OLED shown in FIG. 2;

FIG. 15 is a cross-sectional side view illustrating in greater detail an OLED device containing an array of OLEDs each configured in accordance with a ninth embodiment of the OLED shown in FIG. 2;

FIG. 16 is a cross-sectional side view illustrating in greater detail an OLED device containing an array of OLEDs each configured in accordance with a tenth embodiment of the OLED shown in FIG. 2; and

FIG. 17 is a cross-sectional side view illustrating in greater detail an OLED device containing an array of OLEDs each configured in accordance with an eleventh embodiment of the OLED shown in FIG. 2.

### DETAILED DESCRIPTION OF THE DRAWINGS

Referring to FIGS. 2-17, there are disclosed several embodiments of OLEDs and methods for manufacturing the OLEDs in accordance with the present invention. The OLEDs described herein can be used as discrete light emitting devices or they can be used in a large number of applications including, for example, lighting applications or display applications (e.g., flat-panel displays). Although the present invention is described below with respect to OLEDs and OLED devices (e.g., OLED lighting devices and OLED displays), it should be understood that the same or similar can also be applied to increase the light trapping efficiency of photo-voltaic devices. In this case, the application would be light trapping instead of light extraction. Accordingly, the present invention should not be construed in a limited manner.

Referring to FIG. 2, there is a cross-sectional side view illustrating the basic components of an OLED 200 in accordance with the present invention. The OLED 200 includes a multi-layer sandwich of a transparent substrate 202, a microstructure 204, a first conductive electrode 206 (e.g. anode electrode, cathode electrode), at least one organic layer 208, a second conductive electrode 210 (e.g., cathode electrode, anode electrode) and an encapsulant substrate 212. The OLED 200 emits light 214a, 214b and 214c when a voltage source 216 applies a voltage across the first conductive electrode 206 (e.g., anode electrode) and the second conductive electrode 210 (e.g., cathode electrode). Upon the application of the voltage, electrons are directly injected into the organic layer 208 from the cathode electrode 210 and holes are directly injected into the organic layer 208 from the anode electrode 206. The electrons and holes travel through the organic layer 208 until they recombine to form excited molecules or excitons. The decay of the excited molecules or excitons results in the emission of low angle light 214a and high angle light 214b and 214c.

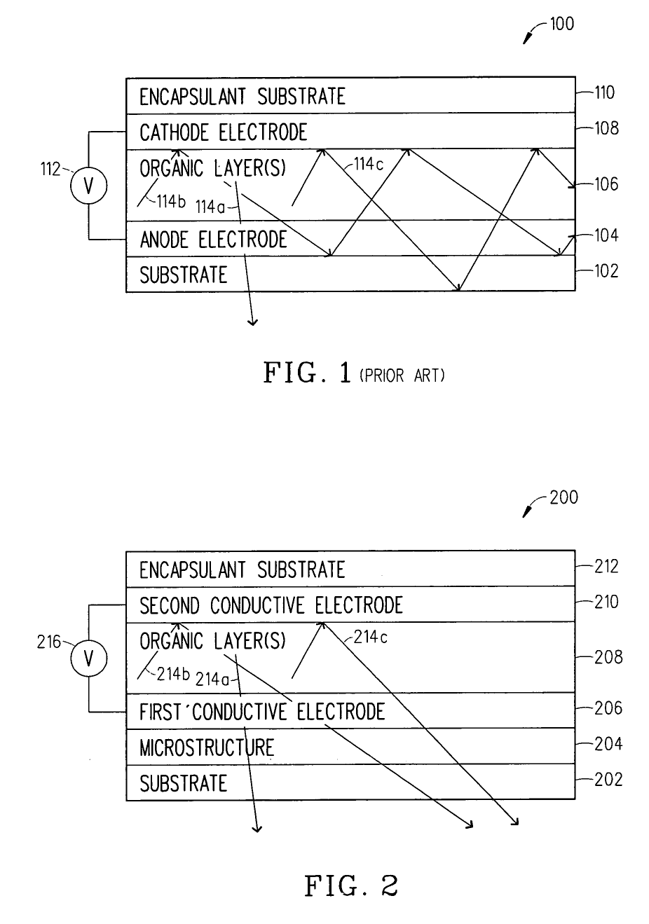

The present invention is directed to increasing the amount of light 214a, 214b and 214c that is emitted from the OLED 200. To accomplish this, the OLED 200 includes the microstructure 204 which enables more light 214a, 214b and 214c to escape the OLED 200 and as a result functions to increase the out-coupling efficiency of the OLED 200. In particular, the microstructure 204 functions to prevent or at least perturb the propagation of internal waveguide modes that confine high angle light 214b and 214c within the OLED 200. Thus, the microstructure 204 allows more light 214a, 214b and 214c to be emitted from the OLED 200 when compared to the traditional OLED 100 shown in FIG. 1.

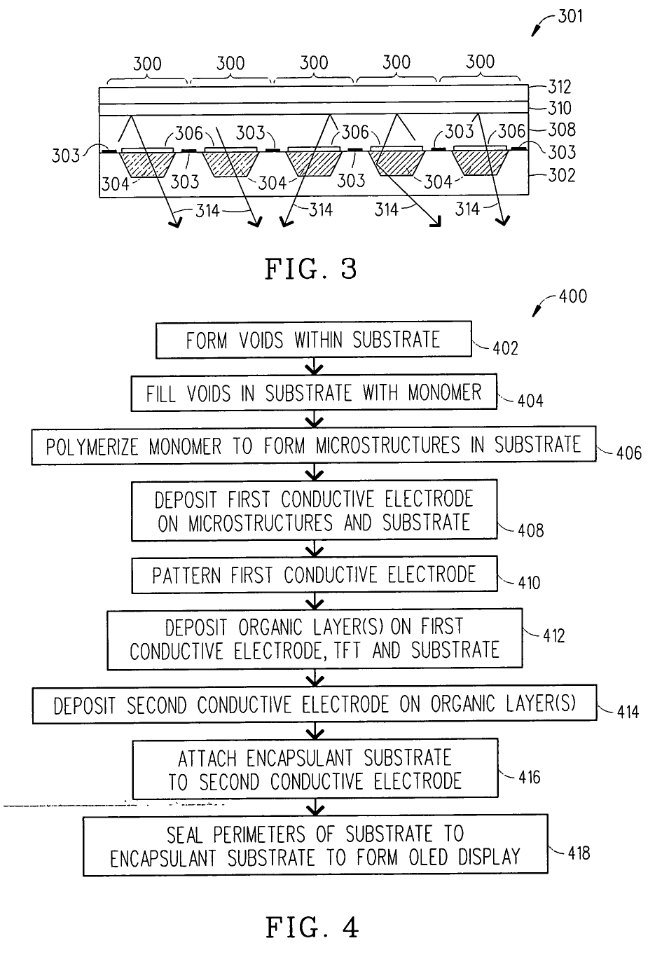

The microstructure 204 is shown in FIG. 2 as being located between the transparent substrate 202 and the first conductive electrode 206 (e.g., anode electrode 206) but it could be located anywhere within the OLED 200. For example, the microstructure 204 could be located between the second conductive electrode 210 (e.g., cathode electrode 210) and the encapsulant substrate 212. In this example, the substrate 202 and first conductive electrode 206 are not required to be optically transparent, but the encapsulant substrate 212 and second conductive substrate 210 are required to be optically transparent. As described below with respect to FIGS. 3-17, the microstructure 204 can be composed of either a physical boundary between different material layers or as a refractive index variation that occurs within a single material layer. Also, these microstructures 204 can either be an orderly and regularly shaped structures or they can be randomly shaped and/or randomly positioned structures.

Referring to FIG. 3, there is a cross-sectional side view illustrating in greater detail an OLED device 301 (e.g., OLED lighting device, OLED display) containing an array of OLEDs 300 which incorporate microstructures 304 configured in accordance with a first embodiment of the present invention. The OLED device 301 (shown as an active OLED display 301) includes an array of bottom emitting OLEDs 300. Each bottom emitting OLED 300 is a multi-layer sandwich comprising in sequence a planar transparent substrate 302, a trapezoidal-shaped prism microstructure 304, a thin film transistor (TFT) 303, a predominately transparent first conductive electrode 306 (e.g. anode electrode, cathode electrode), at least one organic layer 308, a predominately reflective second conductive electrode 310 (e.g., cathode electrode, anode electrode) and an encapsulant substrate 312. It should be understood that the encapsulant substrate 312 need not be a planar component. For example, the encapsulant substrate 312 could be a deposited encapsulating material or materials. Also, the TFTs 303 are shown as discrete elements in the plane of the first conductive electrode 306, but they in fact may incorporate several additional layers (not shown) between the first conductive electrode 306 and the transparent substrate 302. As shown, the bottom emitting OLEDs 300 emit both low angle and high angle light 314 through the first conductive electrodes 306, the trapezoidal-shaped prism microstructures 304 and the transparent substrate 302. Although FIG. 3 illustrates one trapezoidal-shaped prism microstructure 304 contained within each bottom emitting OLED 300, it is also possible to have several microstructures 304 within each emitting OLED 300.

The trapezoidal-shaped prism microstructures 304 can be made from a polymer that is located within voids that were formed within the transparent substrate 302. Ideally, the microstructures 304 and in particular the polymer has an index of refraction that is equal to or higher than the refraction indexes of the first conductive electrode 306 and the organic layer 308. And, if the refractive index of the polymer is higher than that of the transparent substrate 302 then there is an increase in the light extraction efficiency of the OLED device 301. Because, the microstructures 304 have a relatively high refraction index they are able to perturb and can even prevent the propagation of internal waveguide modes within the OLEDs 300 which results in more light 314 being emitted from the OLEDs 300. In the preferred embodiment, the polymer used to make the microstructure 304 can include aromatic segments, sulfur containing segments and/or heavy halogen containing segments (e.g., Cl, Br, I) which can be index matched to the first conductive electrode 306 (e.g., Indium Tin Oxide (ITO) anode electrode 306) and the organic layer 308. In this sense, index matched to the organic layer means having an index closer to the index of organic layer 308 than to the index of the substrate 302. Instead of a polymer, an inorganic material (glass frit for example) can also be used to make the microstructures 304. Alternatively, the microstructures 304 can be made by dispersing nano-particles of metal oxides (e.g., titanium oxide, tin oxide) in weight percentages of up to about 50% within conventional polymers or polymerizable monomers. It should be understood that the TFTs 303 may be omitted from the OLED device 301 and if this is the case then the OLED device 301 would be considered a passive OLED device 301.

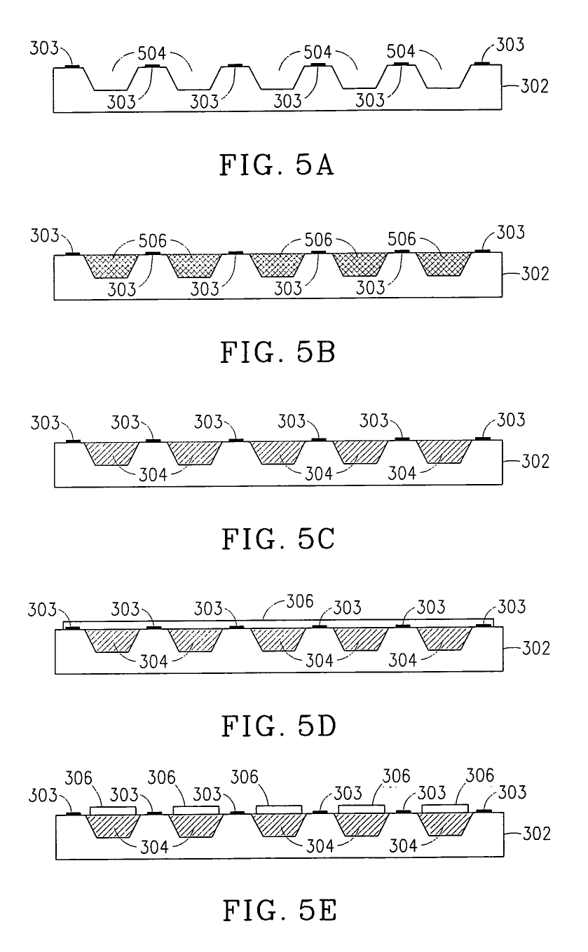

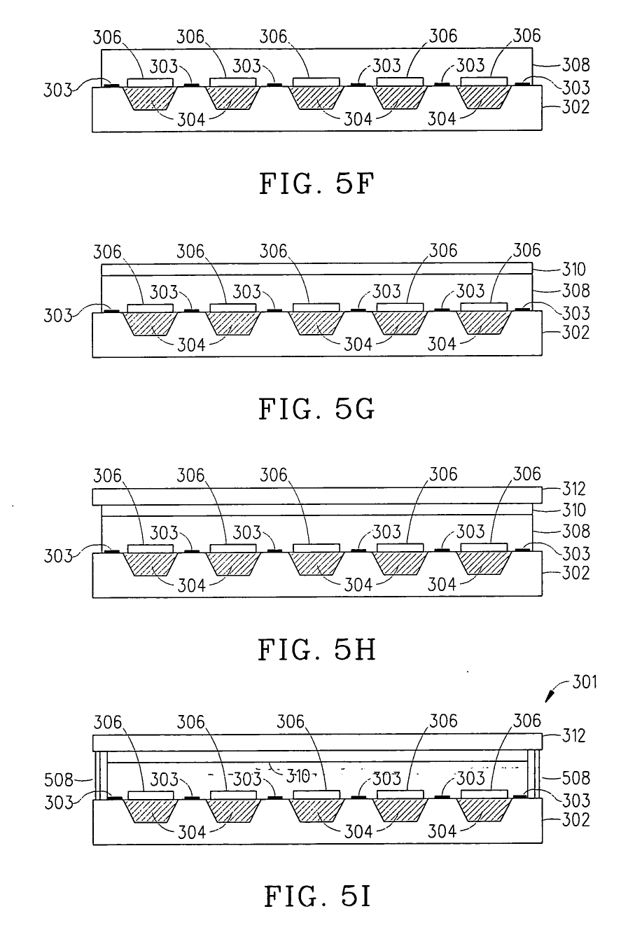

Referring to FIGS. 4 and 5A-5I, there are respectively illustrated a flowchart of the preferred method 400 for manufacturing the OLED device 301 and various cross-sectional side views of the OLED device 301 at different steps in the preferred method 400. Beginning at step 402, the substrate 302 is etched or embossed to form voids 504 within the substrate 302 (see FIG. 5A). In this example, the substrate 302 is glass or a high barrier laminate that has a refractive index of n=1.45. The TFTs 303 may at this point be attached to the substrate 302 if they have not already been attached to the substrate 302. At step 404, the etched substrate 302 has its voids 504 filled in with a monomer 506 (see FIG. 5B). At step 406, the monomer 506 is then polymerized (e.g., photochemically polymerized, thermally polymerized) to form the microstructures 304 (see FIG. 5C). At step 408, the first conductive electrode 306 (e.g., anode electrode 306) is deposited on the microstructures 304 and substrate 302 (see FIG. 5D). In this example, the microstructures 304 have a refractive index of n=1.7 which is the same as the refractive index of the first conductive electrode 306 which in this case is an Indium Tin Oxide (ITO) anode electrode 306. At step 410, the first conductive electrode 306 is patterned into segments to create individual emitting pixels (see FIG. 5E). In this example, the ITO anode electrode 306 is patterned into segments by lithography so as to make the emission areas of the segments smaller than the projected interfaces between the microstructures 304 and the substrate 302. The pattern can include links (not shown) between the segments that electrically interconnect all of the segments. The segments can be aligned in any desired registration with the microstructures 304. At step 412, the organic layer(s) 308 is deposited on the first conductive electrode 306, substrate 302 and TFTs 303 (see FIG. 5F). At step 414, the second conductive electrode 310 (e.g., cathode electrode 310) is deposited on the organic layer(s) 308 (see FIG. 5G). At step 416, the encapsulant substrate 312 is placed on the second conductive electrode 310 (see FIG. 5H). It should be understood that the encapsulant substrate 312 need not be in physical contact with the second conductive electrode 310. Lastly at step 418, the perimeters of the encapulant substrate 312 and substrate 302 are sealed to one another with a frit 508 (for example) or some other sealant so as to form a hermetically sealed OLED device 301 (see FIG. 5I). Alternatively, the frit 508 can be replaced with an organic adhesive, solder, or an encapsulating material placed between the encapsulant substrate 312 and the second conductive electrode 310. Furthermore, the encapsulant substrate 312 and the frit 508 could both be replaced with an encapsulant layer deposited over the entire OLED device 301.

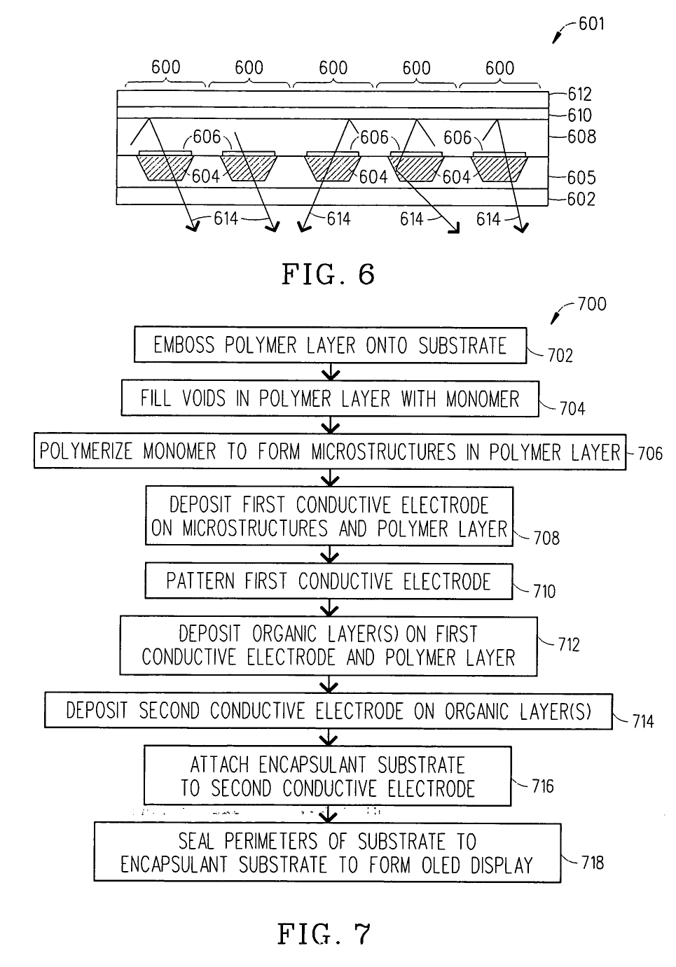

Referring to FIG. 6, there is a cross-sectional side view illustrating in greater detail an OLED device 601 (e.g., OLED lighting device, OLED display) containing an array of OLEDs 600 which incorporate microstructures 604 configured in accordance with a second embodiment of the present invention. The OLED device 601 (shown as a passive OLED display 601) includes an array of bottom emitting OLEDs 600. Each bottom emitting OLED 600 is a multi-layer sandwich comprising in sequence a planar transparent substrate 602, a trapezoidal-shaped prism microstructure 604 formed within a polymer layer 605 (or inorganic layer 605), a predominately transparent first conductive electrode 606 (e.g. anode electrode, cathode electrode), at least one organic layer 608, a predominately reflective second conductive electrode 610 (e.g., cathode electrode, anode electrode) and an encapsulant substrate 612. It should be understood that the encapsulant substrate 612 need not be a planar component. For example, the encapsulant substrate 612 could be a deposited encapsulating material or materials. As shown, the bottom emitting OLEDs 600 emit both low angle and high angle light 614 through the first conductive electrodes 606, the trapezoidal-shaped prism microstructures 604, the polymer layer 605 and the transparent substrate 602. Although FIG. 6 illustrates one trapezoidal-shaped prism microstructure 604 contained within each bottom emitting OLED 600, it is also possible to have several microstructures 604 within each emitting OLED 600.

The trapezoidal-shaped prism microstructures 604 can be made from a polymer that is located within voids formed within the polymer layer 605 that was soft-embossed onto the transparent substrate 602. The polymer layer 605 is index matched to the transparent substrate 602. Ideally, the microstructures 604 and in particular the polymer has an index of refraction that is equal to or higher than the refraction indexes of the first conductive electrode 606 and the organic layer 608. And, if the refractive index of the polymer is higher than that of the transparent substrate 602 then there is an increase in the light extraction efficiency of the OLED device 601. Because the microstructures 604 have a relatively high refraction index they are able to perturb and can even prevent the propagation of internal waveguide modes within the OLEDs 600 which results in more light 614 being emitted from the OLEDs 600. In the preferred embodiment, the polymer used to make the microstructure 604 can include aromatic segments, sulfur containing segments and/or heavy halogen containing segments (e.g., Cl, Br, I) which can be index matched to the first conductive electrode 606 (e.g., Indium Tin Oxide (ITO) anode electrode 606) and the organic layer 608. In this sense, index matched to the organic layer means having an index closer to the index of organic layer 608 than to the index of the substrate 602. Instead of a polymer, an inorganic material (glass frit for example) can also be used to make the microstructures 604. Alternatively, the microstructures 604 can be made by dispersing nano-particles of metal oxides (e.g., titanium oxide, tin oxide) in weight percentages of up to about 50% within conventional polymers or polymerizable monomers. It should be understood that TFTs (not shown) may be included in the OLED device 601 and if this is done then the OLED device 601 would be considered an active OLED display 601.

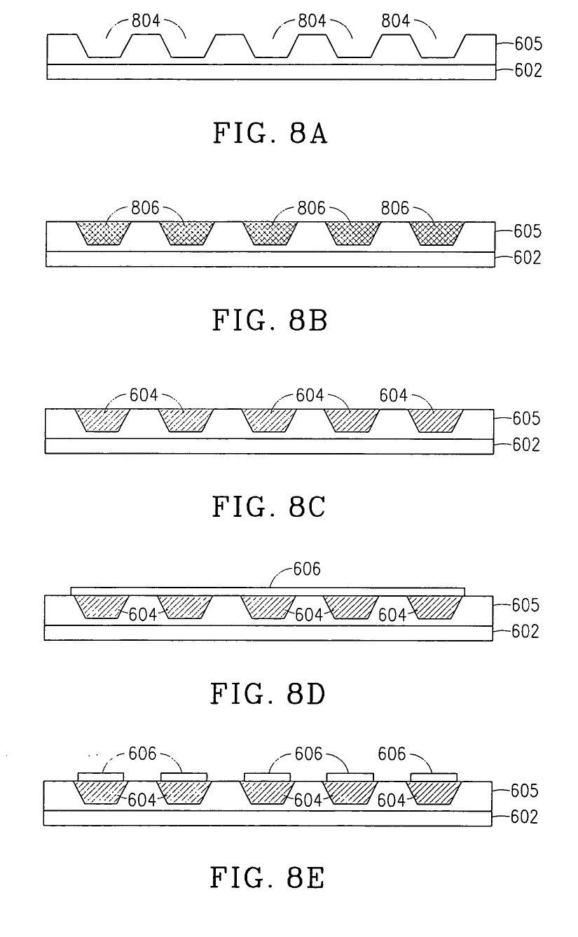

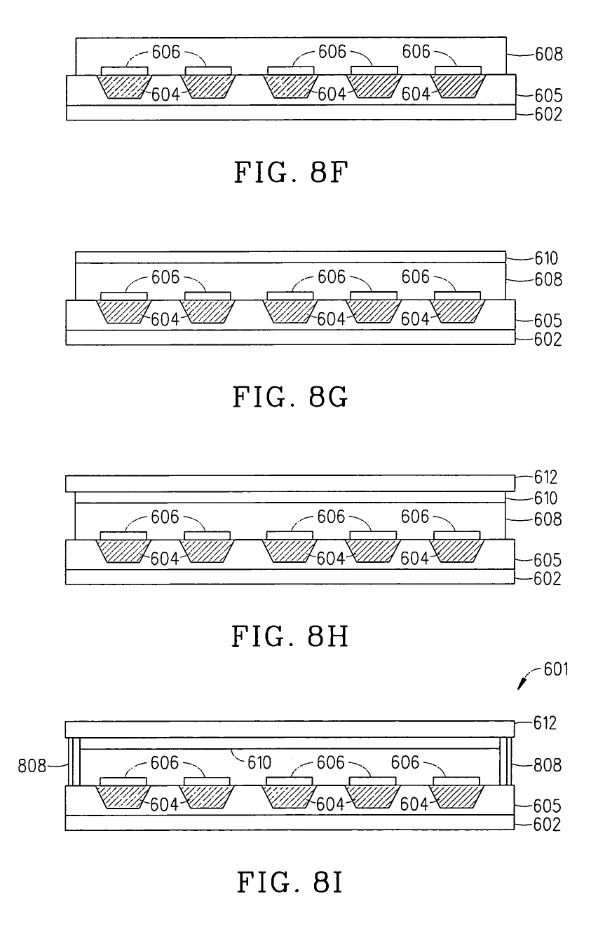

Referring to FIGS. 7 and 8A-81, there are respectively illustrated a flowchart of the preferred method 700 for manufacturing the OLED device 601 and various cross-sectional side views of the OLED device 601 at different steps in the preferred method 700. Beginning at step 702, the polymer layer 605 containing a framework of voids 804 is embossed onto the substrate 602 (see FIG. 8A). Alternatively, the polymer layer 605 can be embossed onto the substrate 602 and then the voids 804 can be formed therein. In this example, the substrate 602 is glass or a high barrier laminate that has a refractive index of n=1.45 and the polymer layer has a matching refractive index of n=1.45. At step 704, the polymer layer 605 has its voids 804 filled in with a monomer 806 (see FIG. 8B). At step 706, the monomer 806 is then polymerized (e.g., photochemically polymerized, thermally polymerized) to form the microstructures 604 (see FIG. 8C). At step 708, the first conductive electrode 606 (e.g., anode electrode 606) is deposited on the microstructures 604 and polymer layer 605 (see FIG. 8D). In this example, the microstructures 604 have a refractive index of n=1.7 which is the same as the refractive index of the first conductive electrode 606 which in this case is an Indium Tin Oxide (ITO) anode electrode 606. At step 710, the first conductive electrode 606 is patterned into segments to create individual pixels (see FIG. 8E). In this example, the ITO anode electrode 606 is patterned into segments by lithography so as to make the emission areas of the segments smaller than the projected interfaces between the microstructures 604 and the polymer layer 605. The pattern can include links (not shown) between the segments that electrically interconnect all of the segments. The segments can be aligned in any desired registration with the microstructures 604. At step 712, the organic layer(s) 608 is deposited on the first conductive electrode 606 and the polymer layer 605 (see FIG. 8F). At step 714, the second conductive electrode 610 (e.g., cathode electrode 610) is deposited on the organic layer(s) 608 (see FIG. 8G). At step 716, the encapsulant substrate 612 is placed on the second conductive electrode 610 (see FIG. 8H). In this example, the encapsulant substrate 612 need not be in physical contact with the second conductive electrode 610. Lastly at step 718, the perimeters of the encapulant substrate 612 and substrate 602 are sealed to one another with a frit 808 (for example) or some other sealant so as to form a hermetically sealed OLED device 601. Alternatively, the frit 808 can be replaced with an organic adhesive, solder, or an encapsulating material placed between the encapsulant substrate 612 and the second conductive electrode 610. Furthermore, the encapsulant substrate 612 and the frit 808 could both be replaced with an encapsulant layer deposited over the OLED device 601.

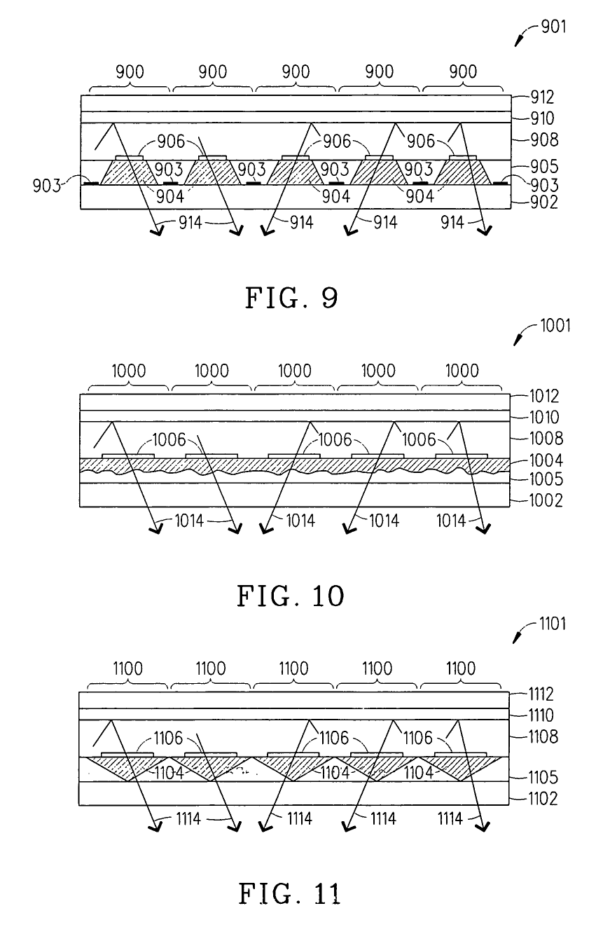

Referring to FIG. 9, there is a cross-sectional side view illustrating in greater detail an OLED device 901 (e.g., OLED lighting device, OLED display) containing an array of OLEDs 900 which incorporate microstructures 904 configured in accordance with a third embodiment of the present invention. The OLED device 901 (shown as an active OLED display 901) includes an array of bottom emitting OLEDs 900. Each bottom emitting OLED 900 is a multi-layer sandwich comprising in sequence a planar transparent substrate 902, a TFT 903, an inverted prism microstructure 904 formed within a polymer layer 905 (or inorganic layer 905), a predominately transparent first conductive electrode 906 (e.g. anode electrode, cathode electrode), at least one organic layer 908, a predominately reflective second conductive electrode 910 (e.g., cathode electrode, anode electrode) and an encapsulant substrate 912. The polymer layer 905 is index matched to the transparent substrate 902. It should be understood that the encapsulant substrate 912 need not be a planar component. For example, the encapsulant substrate 912 could be a deposited encapsulating material or materials. As shown, the bottom emitting OLEDs 900 emit light 914 through the first conductive electrodes 906, the inverted prism microstructures 904, and the transparent substrate 902. The OLEDs 900 have the following characteristics: (1) efficient extraction; (2) strong forward extraction; (3) minimal retro-reflection of light; and (4) first conductive electrodes have relatively small footprints. Although FIG. 9 illustrates one inverted prism microstructure 904 contained within each bottom emitting OLED 900, it is also possible to have several microstructures 904 within each emitting OLED 900.

The microstructures 904 like the aforementioned microstructures 304 and 604 function to prevent or at least perturb the propagation of internal waveguide modes within the OLEDs 900. And, the microstructures 904 can be made from the same type of material used to make microstructures 304 and 604. As such, the microstructure 904 and in particular the material ideally has an index of refraction that is equal to or higher than the refraction indexes of the first conductive electrode 906 and the organic layer 908. And, if the refractive index of the polymer is higher than that of the transparent substrate 902 then there is an increase in the light extraction efficiency of the OLED device 901. It should be understood that the microstructures 904 could be located within the substrate 902 instead of the polymer layer 905. In this case, the polymer layer 905 would not be needed. It should also be understood that the TFTs 903 may be omitted from the OLED device 901. In this case, the OLED device 901 would be considered a passive OLED device 901.

Referring to FIG. 10, there is a cross-sectional side view illustrating in greater detail an OLED device 1001 (e.g., OLED lighting device, OLED display) containing an array of OLEDs 1000 which incorporate microstructures 1004 configured in accordance with a fourth embodiment of the present invention. The OLED device 1001 (shown as a passive OLED display 1001) includes an array of bottom emitting OLEDs 1000. Each bottom emitting OLED 1000 is a multi-layer sandwich comprising in sequence a planar transparent substrate 1002, a rough diffuser microstructure 1004 formed within a polymer layer 1005 (or inorganic layer 1005), a predominately transparent first conductive electrode 1006 (e.g. anode electrode, cathode electrode), at least one organic layer 1008, a predominately reflective second conductive electrode 1010 (e.g., cathode electrode, anode electrode) and an encapsulant substrate 1012. It should be understood that the encapsulant substrate 1012 need not be a planar component. For example, the encapsulant substrate 1012 could be a deposited encapsulating material or materials. The polymer layer 1005 is index matched to the substrate 1002. As shown, the bottom emitting OLEDs 1000 emit light 1014 through the first conductive electrodes 1006, the rough diffuser microstructures 1004, the polymer layer 1005 and the transparent substrate 1002. The OLEDs 1000 have the following characteristics: (1) efficient extraction; (2) first conductive electrodes have large footprints; (3) low retro-reflection of light if diffuser is rough; and (4) retro-reflection of low angle light is possible if diffuser is not rough enough.

The microstructures 1004 like the aforementioned microstructures 304, 604 and 904 function to prevent or at least perturb the propagation of internal waveguide modes within the OLEDs 1000. And, the microstructures 1004 can be made from the same type of polymer or other material used to make microstructures 304, 604 and 904. As such, the microstructure 1004 and in particular the polymer has an index of refraction that is ideally equal to or higher than the refraction indexes of the first conductive electrode 1006 and the organic layer 1008. And, if the refractive index of the polymer is higher than that of the transparent substrate 1002 then there is an increase in the light extraction efficiency of the OLED device 1001. It should be understood that the microstructures 1004 could be located within a rough surface of the substrate 1002 instead of the polymer layer 1005. In this case, the polymer layer 1005 would not be needed. It should also be understood that TFTs may be included within the OLED device 1001. In this case, the OLED device 1001 would be considered an active OLED device 1001.

Referring to FIG. 11, there is a cross-sectional side view illustrating in greater detail an OLED device 1101 (e.g., OLED lighting device, OLED display) containing an array of OLEDs 1100 which incorporate microstructures 1104 configured in accordance with a fifth embodiment of the present invention. The OLED device 1101 (shown as a passive OLED display 1101) includes an array of bottom emitting OLEDs 1100. Each bottom emitting OLED 1100 is a multi-layer sandwich comprising in sequence a planar transparent substrate 1102, a triangular-shaped prism microstructure 1104 formed within a polymer layer 1105 (or inorganic layer 1105), a predominately transparent first conductive electrode 1106 (e.g. anode electrode, cathode electrode), at least one organic layer 1108, a predominately reflective second conductive electrode 1110 (e.g., cathode electrode, anode electrode) and an encapsulant substrate 1112. It should be understood that the encapsulant substrate 1112 need not be a planar component. For example, the encapsulant substrate 1112 could be a deposited encapsulating material or materials. The polymer layer 1105 is index matched to the transparent substrate 1102. As shown, the bottom emitting OLEDs 1100 emit light 1114 through the first conductive electrodes 1106, the triangular-shaped prism microstructures 1104, polymer layer 1105 and the transparent substrate 1102. The OLEDs 1100 have the following characteristics: (1) efficient extraction; (2) first conductive electrodes have large footprints; and (3) significant retro-reflection of low angle light. Although FIG. 11 illustrates one triangular-shaped prism microstructure 1104 contained within each bottom emitting OLED 1100, it is also possible to have several microstructures 1104 within each emitting OLED 1100.

The microstructures 1104 like the aforementioned microstructures 304, 604, 904 and 1004 function to prevent or at least perturb the propagation of internal waveguide modes within the OLEDs 1100. And, the microstructures 1104 can be made from the same type of material used to make microstructures 304, 604, 904 and 1004. As such, the microstructure 11004 and in particular the material has an index of refraction that is ideally equal to or higher than the refraction indexes of the first conductive electrode 1106 and the organic layer 1108. And, if the refractive index of the polymer is higher than that of the transparent substrate 1102 then there is an increase in the light extraction efficiency of the OLED device 1101. It should be understood that the microstructures 1104 could be located within the substrate 1102 instead of the polymer layer 1105. In this case, the polymer layer 1105 would not be needed. It should also be understood that TFTs may be included within the OLED device 1101. In this case, the OLED device 1101 would be considered an active OLED device 1101.

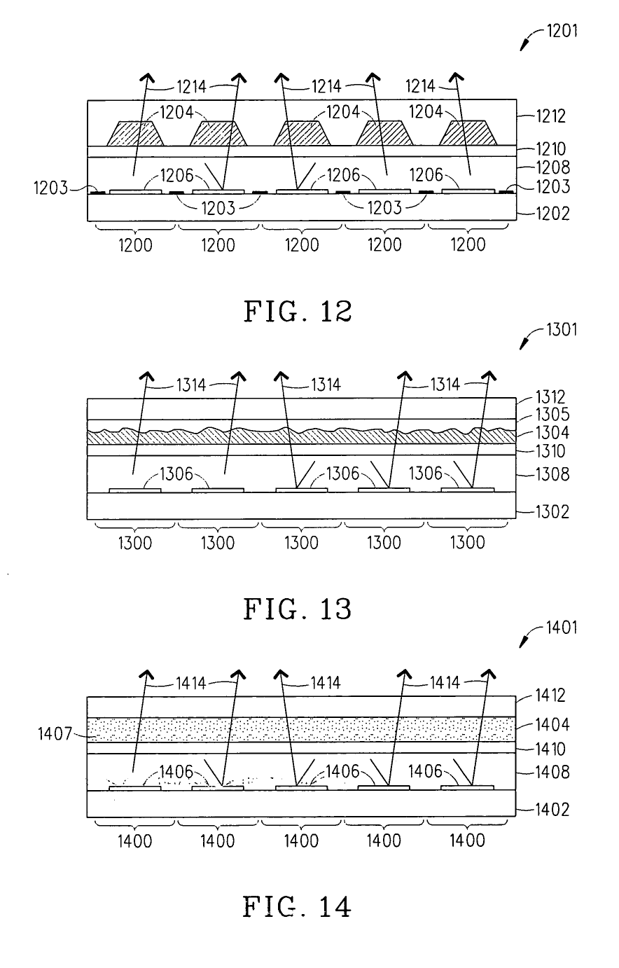

Referring to FIG. 12, there is a cross-sectional side view illustrating in greater detail an OLED device 1201 (e.g., OLED lighting device, OLED display) containing an array of OLEDs 1200 which incorporate microstructures 1204 configured in accordance with a sixth embodiment of the present invention. The OLED device 1201 (shown as an active OLED display 1201) includes an array of top emitting OLEDs 1200. Each top emitting OLED 1200 is a multi-layer sandwich comprising in sequence a planar substrate 1202, predominately reflective first conductive electrode 1206 (e.g. anode electrode, cathode electrode), a TFT 1203, at least one organic layer 1208, a predominately transparent second conductive electrode 1210 (e.g., cathode electrode, anode electrode), a trapezoidal-shaped prism microstructure 1204 and an encapsulant substrate 1212. In this case, the planar substrate 1202 is not required to be transparent. As shown, the top emitting OLEDs 1200 emit light 1214 through the second conductive electrode 1210, the trapezoidal-shaped prism microstructure 1204 and the encapsulant substrate 1212. Although FIG. 12 illustrates one trapezoidal-shaped prism microstructure 1204 contained within each top emitting OLED 1200, it is also possible to have several microstructures 1104 within each emitting OLED 1200.

The microstructures 1204 like the aforementioned microstructures 304, 604, 904, 1004 and 1104 function to prevent or at least perturb the propagation of internal waveguide modes within the OLEDs 1200. And, the microstructures 1204 can be made from the same type of polymer or other material used to make microstructures 304, 604, 904, 1004 and 1104. As such, the microstructure 1204 and in particular the material ideally has an index of refraction that is equal to or higher than the refraction indexes of the second conductive electrode 1210 and the organic layer 1208. And, if the refractive index of the polymer is higher than that of the transparent encapsulant substrate 1212 then there is an increase in the light extraction efficiency of the OLED device 1201.

It should be understood that the microstructures 1204 can have a wide range of geometries besides the shown trapezoidal-shaped prism. For instance, the microstructures 1204 may have shapes like the aforementioned microstructures 304, 604, 904, 1004 and 1104. Likewise the aforementioned microstructures 304, 604, 904, 1004, and 1104 are not limited to the specific geometries mentioned. They can be arbitrarily shaped and arbitrarily positioned. It should also be understood that the microstructures 1204 can be formed within a polymer or other layer (e.g., inorganic layer) which is embossed or attached to the encapsulant layer 1212 instead of being formed within the encapsulant layer 1212. Lastly, it should also be understood that the TFT 1203 may be omitted from the OLED device 1201. In this case, then the OLED device 1201 would be considered a passive OLED device 1201.

Following is a list of some of the additional features and advantages associated with OLEDs 300, 600, 900, 1000, 1100 and 1200:

The microstructures can be any shape besides the shapes discussed above with respect to microstructures 304, 604, 904, 1004, 1104 and 1204 so long as the microstructure can efficiently introduce index perturbations that induce light coupling out of guided modes and allow more light to be emitted from the OLED. For instance, the microstructures can be particles embedded within any of the high-index layers including the anode electrode, cathode electrode or organic layer(s). The particles would have a significantly different index of refraction than the refraction index of the anode electrode, cathode electrode or organic layer(s). Alternatively, particles could be thin film coated with reflective materials to redirect light via surface scattering.

Active OLED displays can be designed with TFTs or other circuitry fabricated on high-temperature substrates such as glass prior to forming the sub-pixel microstrucures (see FIGS. 3 and 9).

The microstructures can be random microstructures (e.g., microstructure 1004) or symmetrical microstructures (e.g., microstructures 304, 604, 904, 1104 and 1204). The symmetrical microstructures can function to perturb the propagation of internal waveguide modes within the OLEDs and as a result allow more light to be emitted in a preferred direction from the OLEDs. In contrast, the random microstructures can function to perturb the propagation of internal waveguide modes within the OLEDs and as a result allows more light to be emitted in any direction from the OLEDs.

The OLEDs of the present invention have a significantly higher lumens-per-watt ratio because the extraction efficiency was enhanced by increasing the projection area relative to the light production area of the OLEDs. Thus, the OLEDs can have a brighter illumination at the same power consumption and device lifetime, or the same illumination is available at lower power and longer device lifetime.

The OLEDs of the present invention can have more energy extracted from them as useful light which means that less energy is converted to heat that would otherwise shorten the OLED's lifetime.

The OLEDs of the present invention can incorporate microstructures which can distribute the output light in a desired direction. For example, symmetric diffuser microstructures can direct light widely and uniformly in a near Lambertian distribution. And, asymmetric diffuser microstructures can compress the output light in one axis. In contrast, inverted prism microstructures can confine the output light to lower angles.

The OLEDs of the present invention can incorporate microstructures that are located between the substrate and a transparent electrode. This configuration can lead to a surface for OLED fabrication that is planar and as such is easier to manufacture. Or, this configuration can lead to a surface for OLED fabrication that is non-planar and as such can take advantage of Bragg scattering in the OLED. Similarly, the microstructures that enhance light extraction from the organic layer to the substrate can also be used in conjunction with substrate surface structures to enhance light extraction from the substrate.

Referring to FIG. 13, there is a cross-sectional side view illustrating in greater detail an OLED device 1301 (e.g., OLED lighting device, OLED display) containing an array of OLEDs 1300 which incorporate microstructures 1304 configured in accordance with a seventh embodiment of the present invention. The OLED device 1301 (shown as a passive OLED display 1301) includes an array of top emitting OLEDs 1300. Each top emitting OLED 1300 is a multi-layer sandwich comprising in sequence a planar substrate 1302, a predominately reflective first conductive electrode 1306 (e.g. anode electrode, cathode electrode), at least one organic layer 1308, a predominately transparent second conductive electrode 1310 (e.g. cathode electrode, anode electrode), a microstructure 1304 located within a rough surface of a polymer layer 1305 (or inorganic layer 1305), and an encapsulant substrate 1312. As shown, the top emitting OLEDs 1300 emit light 1314 through the second conductive electrodes 1310, the microstructures 1304, the polymer layer 1305 and the encapsulant substrate 1312.

The microstructures 1304 ideally can be made from an adhesive which is index matched to the organic layer 1308 and attached to the rough side of the polymer layer 1305. Adhesive in this case means any organic or inorganic material that can make optical contact to and bond the second conductive electrode 1310 to the polymer layer 1305. The polymer layer 1305 is index matched and soft-embossed onto the encapsulant substrate 1312. Additionally, the polymer layer 1305 can be replaced with an inorganic layer that performs the same scattering functions. The microstructures 1304 have a relatively high refraction index and as such they are able to perturb and can even prevent the propagation of internal waveguide modes within the OLEDs 1300 which results in more light 1314 being emitted from the OLEDs 1300. It should be understood that TFTs (not shown) may be included in the OLED device 1301 and if this is the case then the OLED device 1301 would be considered an active OLED device 1301.

Referring to FIG. 14, there is a cross-sectional side view illustrating in greater detail an OLED device 1401 (e.g., OLED lighting device, OLED display) containing an array of OLEDs 1400 which incorporate scattering particles 1407 configured in accordance with an eighth embodiment of the present invention. The OLED device 1401 (shown as a passive OLED display 1401) includes an array of top emitting OLEDs 1400. Each top emitting OLED 1400 is a multi-layer sandwich comprising in sequence a planar substrate 1402, a predominately reflective first conductive electrode 1406 (e.g. anode electrode, cathode electrode), at least one organic layer 1408, a predominately transparent second conductive electrode 1410 (e.g. cathode electrode, anode electrode), an adhesive or polymer layer 1404 shown embedded with particles 1407, and an encapsulant substrate 1412. As shown, the top emitting OLEDs 1400 emit light 1414 through the second conductive electrodes 1410, the polymer layer 1404 and the encapsulant substrate 1412.

The adhesive layer 1404 can be made from an adhesive that has embedded therein high index particles 1407 (e.g., glass microspheres). Alternatively, the particles 1407 could be thin film coated with reflective materials to redirect light via surface scattering. In one case, the polymer/adhesive layer 1404 is index matched to the encapsulant substrate 1412, and the particles 1407 have a much higher refractive index than the polymer/adhesive 1404. In another case, the polymer/adhesive layer 1404 index matches to the encapsulant substrate 1412, and the particles 1407 have much lower index than the polymer/adhesive layer 1404. In the preferred embodiment, the high index particles 1407 can be glass particles with an refractive index up to 2.2. The particles 1407 have a relatively high refraction index and as such they are able to perturb and can even prevent the propagation of internal waveguide modes within the OLEDs 1400 which results in more light 1414 being emitted from the OLEDs 1400. In fact, the output-efficiency of the OLEDs 1400 can be controlled by the size and refraction index of the particles 1407. In another case, the particles 1407 could actually be air voids having a much lower refractive index than the polymer/adhesive layer 1404. It should be understood that TFTs (not shown) may be included in the OLED device 1401 and if this is the case then the OLED device 1401 would be considered an active OLED device 1401.

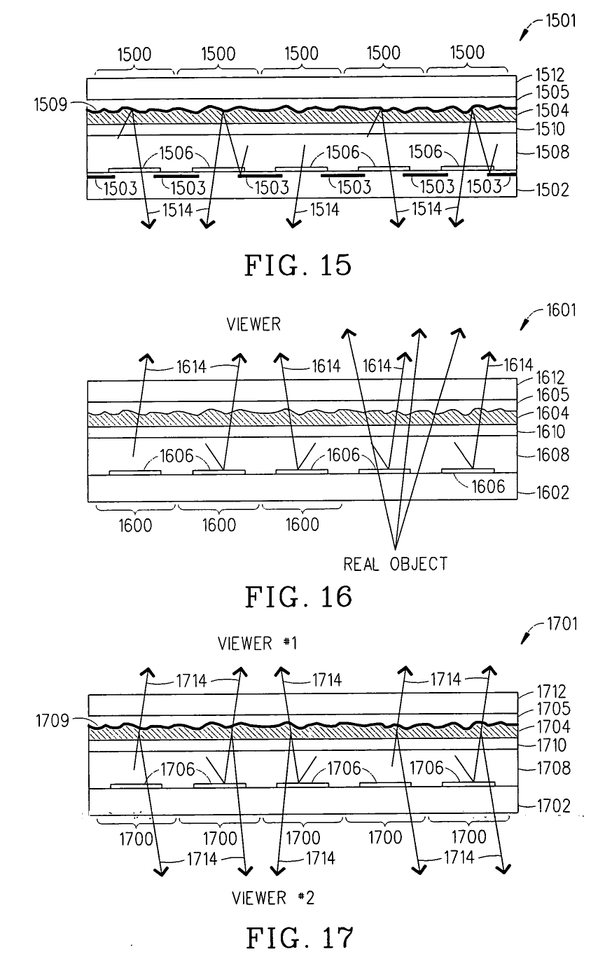

Referring to FIG. 15, there is a cross-sectional side view illustrating in greater detail an OLED device 1501 (e.g., OLED lighting device, OLED display) containing an array of OLEDs 1500 which incorporate microstructures 1504 configured in accordance with a ninth embodiment of the present invention. The OLED device 1501 (shown as an active OLED display 1501) includes an array of bottom emitting OLEDs 1500. Each bottom emitting OLED 1500 is a multi-layer sandwich comprising in sequence a planar transparent substrate 1502, silicon circuitry such as TFTs 1503, a predominately transparent first conductive electrode 1506 (e.g. anode electrode, cathode electrode), at least one organic layer 1508, a predominately transparent second conductive electrode 1510 (e.g. cathode electrode, anode electrode), a microstructure 1504 located within a rough surface of a reflective layer 1509 attached to a polymer layer 1505 (or inorganic layer 1505), and an encapsulant substrate 1512. As shown, the bottom emitting OLEDs 1500 emit light 1514 through the microstructures 1504, the second conductive electrode 1510, the organic layer 1508, the first conductive electrodes 1506 and the substrate 1502.

The microstructures 1504 can be made from an adhesive which is ideally index matched to the organic layer 1508 and attached to the rough surface of a reflective layer 1509 which is attached the polymer layer 1505. The polymer layer 1505 is soft-embossed onto the encapsulant substrate 1512. In an alternative not shown, the microstructures 1504 can be made from adhesive which has embedded therein high index glass particles, low index voids, or other scattering particles. (see FIG. 14). In this case, the polymer layer 1505 can be eliminated, and the reflector 1509 can be applied directly to the encapsulant substrate 1512. In either case, the microstructure 1504 has a relatively high refraction index difference compared to either the rough reflector 1509 or the particles and as such it is able to perturb and can even prevent the propagation of internal waveguide modes within the OLEDs 1500 which results in more light 1514 being emitted from the OLEDs 1500. It should be appreciated that the TFTs 1503 (e.g., silicon circuitry) can block light 1514 but the features of the microstructures 1504 can be used to direct the light 1514 between the TFTs 1503. It should be understood that if TFTs 1503 are not included in the OLED device 1501 then the OLED device 1501 would be considered a passive OLED device 1501.

Referring to FIG. 16, there is a cross-sectional side view illustrating in greater detail a heads-up OLED device 1601 (e.g., OLED lighting device, OLED display) containing an array of OLEDs 1600 which incorporate microstructures 1604 configured in accordance with a tenth embodiment of the present invention. The OLED device 1601 (shown as a passive OLED display 1601) includes an array of top emitting OLEDs 1600. Each top emitting OLED 1600 is a multi-layer sandwich comprising in sequence a planar transparent substrate 1602, a partially transparent first conductive electrode 1606 (e.g. anode electrode, cathode electrode), at least one organic layer 1608, a partially transparent second conductive electrode 1610 (e.g. cathode electrode, anode electrode), a microstructure 1604 located within a rough surface of a polymer layer 1605, and an encapsulant substrate 1612. As shown, a viewer on one side of the OLED display 1601 is able to see the display image shown as light 1614 and a real object located on the other side of the OLED display 1601.

The microstructures 1604 can be made from an adhesive which is ideally index matched to the organic layer 1608 and attached to the rough surface of a polymer layer 1605. The polymer layer 1605 is index matched and soft-embossed onto the encapsulant substrate 1612. In an alternative not shown, the microstructures 1604 can be made from adhesive which is index matched to the encapsulant substrate 1612 and has embedded therein high index glass particles, low index voids, or other scattering particles (see FIG. 14). In either case, the microstructure 1604 has a relatively high refraction index difference and as such it is able to perturb and can even prevent the propagation of internal waveguide modes within the OLEDs 1600 which results in more light 1614 being emitted from the OLEDs 1600. It should be understood that TFTs (not shown) may be included in the OLED device 1601 and if this is the case then the OLED device 1601 would be considered an active OLED device 1601. Lens structures could also be integrated into the microstructure layer 1604 via embossing or some other method to direct light emitted from the heads-up OLED device 1601 in an angular distribution similar to the angular distribution of rays observed from a distant object.

Referring to FIG. 17, there is a cross-sectional side view illustrating in greater detail a heads-up OLED device 1701 (e.g., OLED lighting device, OLED display) containing an array of OLEDs 1700 which incorporate microstructures 1704 configured in accordance with an eleventh embodiment of the present invention. The OLED device 1701 (shown as a passive OLED display 1701) includes an array of hybrid emitting OLEDs 1700. Each hybrid emitting OLED 1700 is a multi-layer sandwich comprising in sequence a planar transparent substrate 1702, a partially transparent first conductive electrode 1706 (e.g. anode electrode, cathode electrode), at least one organic layer 1708, a partially transparent second conductive electrode 1710 (e.g. cathode electrode, anode electrode), a microstructure 1704 located within a rough surface of a partially reflective layer 1709 attached to a polymer layer 1705 (or inorganic layer 1505), and an encapsulant substrate 1712. As shown, a viewer on one side of the OLED device 1701 is able to see the device image shown as light 1714 and another viewer on the other side of the OLED device 1701 is also able to see the device image shown as light 1714.

The microstructures 1704 can be made from an adhesive which is ideally index matched to the organic layer 1708 and attached to the reflective rough surface 1709 of a polymer layer 1705. The polymer layer 1705 is index matched and soft-embossed onto the encapsulant substrate 1712. In an alternative not shown, the microstructures 1704 can be made from adhesive which is index matched to the encapsulant substrate 1712 and has embedded therein high index glass particles, low index voids, or other scattering particles (see FIG. 14). In either case, the microstructure 1704 has a relatively high refraction index difference and as such it is able to perturb and can even prevent the propagation of internal waveguide modes within the OLEDs 1700 which results in more light 1714 being emitted from the OLEDs 1700. It should be understood that the OLEDs 1700 can be designed so that equal power or some predetermined ratio of powers is emitted from each side of the OLED device 1701. It should also be understood that TFTs (not shown) may be included in the OLED device 1701 and if this is the case then the OLED device 1701 would be considered an active OLED device 1701.

Following is a list of some of the additional features and advantages associated with OLEDs 1200, 1300, 1400, 1500, 1600 and 1700:

The polymer layer which is embossed to the encapsulant substrate can be eliminated if the encapsulant substrate has one rough side facing toward the device.

A manufacturer of the encapsulant substrate/polymer/microstrucutures could sell this combination to another manufacturer of a standard OLED who could then easily attach (e.g., glue) the encapsulant substrate/polymer/microstructures to the standard OLED. The standard OLED includes a substrate, a first conductive electrode (e.g. anode electrode, cathode electrode), organic layers, and a second conductive electrode (e.g. cathode electrode, anode electrode). Of course, the manufacturer of the standard OLED would have to make sure that the second conductive electrode is at least partially transparent.

The microstructures which have the proper angles and index matching can function to effectively eliminate waveguiding in both the organic layers and in the substrates.

Similar designs of the encapsulant substrate/polymer/microstructures can be used to improve light extraction in bottom emitting OLEDs, top emitting OLEDs, and hybrid transparent OLED displays. The designs may only differ on the reflective coating that may or may not be deposited. Thus, the manufacturing steps needed to make different types of OLEDs would be similar if not the same.

The OLEDs have designs which incorporate the microstructures within the actual device. Whereas, traditional light extraction techniques placed lenses on the outside of the display glass. By being located within the device, the microstructures are protected from deterioration and abrasion from the outside environment such as fingers touching the display. Also, because the microstructures are inside the OLED device, they are in close proximity to the actual pixels. This means the thickness of the display substrate has a reduced effect on light extraction performance.

The encapsulant substrate (e.g., glass) can tolerate small surface defects. Thus, the manufacturer can use encapsulant substrate which would not ordinarily meet the quality requirements for other applications. For example, substrate glass with small-scale surface defects may be un-useable in the traditional OLEDs because it would cause too many defects in the Si circuitry fabricated on top of it. However, this same glass could be used in the OLEDs of the present invention as the encapsulant substrate.

The approach of the present invention does not affect the display substrate on which the Si circuitry and OLED pixels are fabricated on. Because, the encapsulant substrate/polymer/microstructure is added at the last assembly step. And, since the encapsulant substrate/polymer/microstructure is the last element in the assembly process, the polymer and microstructures do not need to survive the extreme Si or ITO fabrication steps.

Similar light extraction microstructures can be used for both OLED display and lighting applications. Modifications may be required, though, in order to retain the pixel resolution required for display applications.

The divergence angle of the emitted light from the OLEDs can be controlled through proper design of the microstructures or scattering particles. This can occur in top emitting, bottom emitting, and hybrid devices. For example, the light emitted in a heads-up display application can be within a narrow divergence angle directed towards a single viewer. In large display applications, however, light can be spread across the full field of view in order to be seen by a large group of viewers with various viewing angles.

The bottom emitting OLEDs and hybrid OLEDS have an improved light extraction by using the microstructures and a reflector or partial reflector. These structures can be assembled on top of a fabricated OLED as the final processing step and as such do not require the reflector and microstructures to survive any additional processing steps.

Following is a list of exemplary materials that can be used to make the aforementioned OLEDS:

Substrate: Corning's 1737 or Eagle 2000™ glass substrates, higher index glasses, polymer/composite substrates that provide moisture and oxygen barriers.

Transparent anode: ITO.

Reflective anode: Ag/ITO.

Organic layers (e.g., emissive, transport, and other electrical organic layers): varies depending on the chemical company.

Transparent cathode: Ca/ITO, ZnSe, ZnS, co-doped zinc oxide (PCT Patent Application WO 0124290), CuPc/ITO.

Reflective cathode: Mg:Ag/ITO, Ca, LiF/Al.

Adhesive: For an example see PCT Patent Application WO 02/31026 which is hereby incorporated by refererence herein.

Polymer: Norland Optical Adhesive —NOA61, Masterbond UVI5, several others with varying indices.

Encapsulant substrate: same as substrate in addition to vacuum deposited glass layers and organic/inorganic laminated layers. This does not need to be a rigid sheet. Flexible films can also be utilized in the OLED devices, and then the bottom emitting devices would only require a deposited layer. It should be understood that “encapsulant substrate” can be any type of general “encapsulant layer” known in industry.

Although several embodiments of the present invention have been illustrated in the accompanying Drawings and described in the foregoing Detailed Description, it should be understood that the invention is not limited to the embodiments disclosed, but is capable of numerous rearrangements, modifications and substitutions without departing from the spirit of the invention as set forth and defined by the following claims.

What is claimed is:

1. A light emitting device comprising:
a substrate;
a first conductive electrode;
at least one organic layer;
a second conductive electrode;
an encapsulant substrate; and
a microstructure, located within said device, that has internal refractive index variations or internal or surface physical variations that function to perturb the propagation of internal waveguide modes within said device and as a result allows more light to be emitted from said device.

2. The light emitting device of claim 1, wherein said microstructure is a symmetrical microstructure which functions to perturb the propagation of internal waveguide modes within said device and as a result allows more light to be emitted in a preferred direction from said device.

3. The light emitting device of claim 1, wherein said microstructure is located between said substrate and said first conductive electrode.

4. The light emitting device of claim 1, wherein said microstructure is located between said encapsulant substrate and said second conductive electrode.

5. The light emitting device of claim 1, wherein said microstructure is a trapezoidal-shaped prism microstructure located within said substrate or encapsulant substrate or between said substrate and said first conductive electrode or between said encapsulant substrate and said second conductive layer.

6. The light emitting device of claim 1, wherein said microstructure is a triangular-shaped prism microstructure located within said substrate or encapsulant substrate or between said substrate and said first conductive electrode or between said encapsulant substrate and said second conductive layer.

7. The light emitting device of claim 1, wherein said microstructure is an inverted prism microstructure located within said substrate or encapsulant substrate or between said substrate and said first conductive electrode or between said encapsulant substrate and said second conductive layer.

8. The light emitting device of claim 1, wherein said microstructure is a rough diffuser microstructure located within said substrate or encapsulant substrate or between said substrate and said first conductive electrode or between said encapsulant substrate and said second conductive layer.

9. The light emitting device of claim 1, wherein said microstructure is a plurality of particles or voids located within said first conductive electrode, said organic layer, said second conductive electrode, or within a separate microstructure layer.

10. The light emitting device of claim 1, wherein said microstructure is located within said substrate or said encapsulant substrate or between said substrate and said first conductive layer or between said encapsulant substrate and said second conductive electrode.

11. The light emitting device of claim 1, wherein said microstructure is an adhesive that is index matched to said organic layer and located between said second conductive electrode and a rough surface adjacent to or on said encapsulant substrate or between said first conductive electrode and a rough surface adjacent to or on said substrate.

12. The light emitting device of claim 1, wherein said microstructure is an adhesive embedded with particles or voids that is located between said second conductive electrode and said encapsulant substrate or between said first conductive electrode and said substrate, where said particles or voids have a different index of refraction than said adhesive which is indexed matched to said encapsulant substrate, said substrate, or said organic layer.

13. The light emitting device of claim 1, wherein said microstructure is an adhesive that is index matched to said organic layer and located between said second conductive electrode and a reflective rough surface adjacent to or on said encapsulant substrate.

14. The light emitting device of claim 1, wherein said microstructure is an adhesive that is index matched to said organic layer and located between said second conductive electrode and a rough surface adjacent to or on said encapsulant substrate or between said first conductive electrode and a rough surface adjacent to or on said substrate.

15. The light emitting device of claim 1, wherein said microstructure is an adhesive embedded with particles or voids that is located between said second conductive electrode and said encapsulant substrate, where said particles or voids have a different index of refraction than said adhesive which is indexed matched to said encapsulant substrate or said organic layer. (I believe this claim is the same as claim #12.)

16. The light emitting device of claim 1, wherein said microstructure is an adhesive that is index matched to said organic layer and located between said second conductive electrode and a partially reflective rough surface adjacent to or on said encapsulant substrate.

17. The light emitting device of claim 1, wherein said light emitting device incorporates thin film transistors.

18. The light emitting device of claim 1, wherein said light emitting device is:
a bottom light emitting device;
a top light emitting device; or
a transparent light emitting device.

19. A method for manufacturing a light emitting device comprising:
a substrate;
a first conductive electrode;
at least one organic layer;
a second conductive electrode; and
an encapsulant substrate, said method comprising the following step:
incorporating within said device a microstructure that has internal refractive index variations or internal or surface physical variations that function to perturb the propagation of internal waveguide modes within said device and as a result allows more light to be emitted from said device.

20. The method of claim 19, wherein said step of incorporating a microstructure within said device further includes:
applying a polymer to said substrate or said encapsulant substrate;
forming a void within said polymer;
filing said void with a monomer; and
polymerizing said monomer to form said microstructure within said polymer.

21. The method of claim 19, wherein said step of incorporating a microstructure within said device further includes:
forming a void within said substrate or said encapsulant substrate;
filing said void with a monomer; and
polymerizing said monomer to form said microstructures within said substrate or said encapsulant substrate.

22. The method of claim 19, wherein said step of incorporating a microstructure within said device further includes:
applying a polymer to said encapsulant substrate or said subsrate;
forming a rough surface within said polymer; and
filing voids within said rough surface with an adhesive.

23. The method of claim 22, wherein said forming step further includes embossing said polymer to form the rough surface.

24. The method of claim 19, wherein said step of incorporating a microstructure within said device further includes:
applying a polymer to said encapsulant substrate or said substrate;
applying an adhesive embedded with particles that have a different index of refraction than said adhesive which is indexed matched to said encapsulant substrate, said susbtrate, or said organic layer.

25. The method of claim 24, wherein said particles are reflective materials to redirect light via surface scattering.

26. The method of claim 19, wherein said microstructure is a symmetrical microstructure which functions to perturb the propagation of internal waveguide modes within said device and as a result allows more light to be emitted in a preferred direction from said device.

27. The method of claim 19, wherein said microstructure has a higher index of refraction than said substrate.

28. The method of claim 19, wherein said microstructure has a higher index of refraction than said encapsulant substrate.

29. The method of claim 19, wherein said microstructure includes:
a trapezoidal-shaped prism microstructure;
a triangular-shaped prism microstructure;
an inverted prism microstructure;
a rough diffuser microstructure;
particles or voids that are embedded within and have a different index of refraction than said first conductive electrode, said organic layer or said second conductive electrode;
an adhesive embedded with differing index particles or voids that is located between said encapsulant substrate and said second conductive electrode or located between said substrate and said first conductive electrode;
an adhesive that is index matched to said organic layer and located between said second conductive electrode and a rough surface adjacent to or on said encapsulant substrate; or
an adhesive that is index matched to said organic layer and located between said first conductive electrode and a rough surface adjacent to or on said substrate.

30. The method of claim 19, wherein said light emitting device is:
an organic light emitting diode;
a polymer organic light emitting diode; or
a small-molecule organic light emitting diode.

31. The method of claim 19, wherein said light emitting device is:
a bottom light emitting device;
a top light emitting device; or
a transparent light emitting device.

32. The method of claim 19, wherein said light emitting device incorporates thin film transistors.

33. A top emitting organic light emitting device comprising:
a substrate;
a first conductive electrode;
at least one organic layer;
a second transparent conductive electrode; and
an adhesive that is index matched to said organic layer and located between said second transparent conductive electrode and a rough surface adjacent to or on an encapsulant substrate.

34. A top emitting organic light emitting device comprising:
a substrate;
a first conductive electrode;
at least one organic layer;
a second transparent conductive electrode; and
an adhesive embedded with particles or voids that is located between said second transparent conductive electrode and an encapsulant substrate, where said particles or voids have a different index of refraction than said adhesive which is indexed matched to said organic layer or encapsulant substrate.

35. A bottom emitting organic light emitting device comprising:
a substrate;
a first conductive electrode;
at least one organic layer;
a second transparent conductive electrode; and
an adhesive that is index matched to said organic layer and located between said second transparent conductive electrode and a reflective rough surface adjacent to or on an encapsulant substrate.

36. The bottom emitting organic light emitting device of claim 35, wherein said reflective rough surface includes features that help focus light between transistors and out of the device.

37. A bottom emitting organic light emitting device comprising:
a substrate;
a first conductive electrode;
at least one organic layer;
a second transparent conductive electrode; and
an adhesive embedded with particles or voids that is located between said second transparent conductive electrode and a reflective surface adjacent to or on an encapsulant substrate, where said particles or voids have a different index of refraction than said adhesive which is indexed matched to said organic layer or encapsulant substrate.

38. The bottom emitting organic light emitting device of claim 37, wherein said reflective surface includes features that help focus light between transistors and out of the device.
